(19) United States
(12) Patent Application Publication
(10) Pub. No.: US 2010/0269907 A1
(43) Pub. Date: Oct. 28, 2010

(54) THIN-FILM SOLAR CELL HAVING A MOLYBDENUM-CONTAINING BACK ELECTRODE LAYER

(75) Inventors: Harald Lackner, Zwentendorf (AT); Gerhard Leichtfried, Reutte (AT); Nikolaus Reinfried, Lechaschau (AT); Jörg Winkler, Reutte (AT)

Correspondence Address: LERNER GREENBERG STEMER LLP, P O BOX 2480, HOLLYWOOD, FL, 33022-2480, US

(73) Assignee: PLANSEE METALL GMBH, Reutte (AT)

(21) Appl. No.: 12/809,162

(22) PCT Filed: Dec. 16, 2008
(86) PCT No.: PCT/AT08/00454

§ 371 Date: Jun. 18, 2010

(30) Foreign Application Priority Data
Dec. 18, 2007 (AT) GM 750/2007

(51) Int. Cl. H01L 31/0272; H01L 31/02; C23C 14/34

(52) U.S. Cl. 136/264; 136/252; 204/192.17; 204/298.13

(57) ABSTRACT

A thin-film solar cell has a rear electrode layer formed of at least 50 atom % of Mo, which in addition to the common contaminants includes 0.1 to 45 atom % of at least one element from the group of Ti, Zr, Hf, V, Nb, Ta, and W, 0 to 7.5 atom % of Na, and 0 to 7.5 atom % of at least one element forming a compound with Na that has a melting point >500 C. The rear electrode layer has good long-term resistance and bonding with the CIGS absorber layer. In addition, the constancy of the alkali metal integration in the absorber layer is improved.

The invention relates to a thin-film solar cell comprising at least one substrate, a back electrode layer, a chalcopyrite absorber layer and a front contact layer, where the back electrode layer is made up of one or more coating layers. The invention further relates to a sputtering target for producing a back electrode layer having a molybdenum content of >50 atom %.

Thin-film solar cells are promising alternatives to conventional silicon solar cells since they make possible a significant saving in material combined with inexpensive production processes. A thin-film solar cell usually comprises a substrate, a back electrode, in general a molybdenum layer applied by cathode atomisation and having a thickness of from about 0.4 to 1.2 μm, an absorber layer having a thickness of from 2 to 5 μm, an n-doped window layer and a transparent, electrically conductive front contact layer.

The photoelectrically active absorber layer is a compound semiconductor layer which has a crystalline or amorphous structure and is based on chalcopyrite and comprises ternary, quaternary or penternary compounds with stoichiometric or nonstoichiometric proportions of the respective chemical elements, e.g. in the form of Cu(Inₓ,Ga₁₋ₓ)(Se_{y},S_{1-y})₂, referred to as CIGS for short. This layer absorbs incident, visible light or nonvisible electromagnetic radiation and converts this into electric energy. It has been able to be shown that efficiencies of up to 19.5% can be achieved by means of CIGS solar cells (Green, M. A. et al.: Prog. Photovolt. Res. Appl. 13 (2005) 49). Industrially manufactured modules at present have an efficiency of up to 13.4% (Green, M. A. et al.: Prog. Photovolt. Res. Appl. 13 (2005) 49). To achieve a high efficiency, it is necessary for alkali metals to be incorporated into the CIGS absorber layer. Studies have shown that sodium produces the greatest increase in efficiency, followed by potassium and lithium, while caesium has virtually no influence (Rudmann, D: Thesis, ETH Zurich, 2004, page viii). Typical sodium concentrations are in the order of 0.1 atom %.

This improvement in efficiency is attributed to both electronic and structural effects. The structural effects include the favourable influence of alkali metals on the growth of the layer and the morphology of the layer. An electronic effect is the increase in the effective charge carrier density and the conductivity, as a result of which an increase in the open-circuit voltage of the cell is achieved. Since an addition of alkali metal during or after deposition of the CIGS layer also leads to an increase in the efficiency, it can be assumed that the electronic effects, probably at grain boundaries, predominate.

Sodium is preferentially present at the grain boundaries since the solubility of sodium in the CIGS layer is very low. The doping of the absorber layer with the alkali metal can be effected by diffusion of the alkali metal, preferably sodium, from the soda-lime glass substrate through the molybdenum back electrode layer. This method is restricted to rigid glass substrates. In addition, a satisfactory process constancy is not ensured.

In order to achieve sodium doping of the absorber layer even when other substrate materials which do not contain sodium, for example steel, titanium or plastic films, used and additionally to improve the process constancy, EP 0 715 358 A2 proposes a process in which sodium, potassium or lithium or a compound of these elements is metered in during deposition of the absorber layer. The addition of the alkali metals or compounds thereof with oxygen, sulphur, selenium or the halides can, for example, be effected by vaporisation from an effusion cell or from a linear vaporiser. The introduction of sodium, potassium or lithium during sputtering of the back electrode layer from a metal target admixed with the alkali element is also mentioned.

However, since alkali metals are very reactive, incorporation of oxygen cannot be prevented. The incorporation of oxygen influences both the proportion of unbound sodium capable of diffusion and also the porosity and conductivity of the molybdenum back electrode layer. Furthermore, it can be assumed that the oxygen also has an influence on the formation of an MoSeₓ/MoSₓ layer in the interface of back electrode layer/CIGS absorber layer.

Kohara et al. (Sol. Energy Mater. Sol. Cells 67 (2001) 209) presume that an MoSeₓ layer having a thickness of a few 10 nm is responsible for the formation of an advantageous ohmic contact in the interface of CIGS absorber layer/back electrode layer. Not only the absolute magnitude of the oxygen value but also the constancy of this value is critical for reliable manufacture of thin-film solar cells having a high and constant efficiency. A constant oxygen value can be set, for example, by introducing sodium into the molybdenum back electrode layer by ion implantation. However, this process is very complicated and is at present used only for scientific studies.

The molybdenum back electrode layer is deposited on the substrate by PVD processes proceeding from a sputtering target. For the present purposes, a sputtering target is a solid from which atoms are removed by bombardment with high-energy ions, go over into the gas phase and are deposited on a substrate. This process is referred to as cathode atomisation or sputtering. Process variants are, for example, DC sputtering, RF sputtering, magnetron sputtering, reactive sputtering and ion beam sputtering. When deformable substrates are used, the sputtered molybdenum layer can be densified by rolling, as described in WO 2005/096395.

The molybdenum back electrode layer can also be made up of two coating layers. Here, one coating layer is doped with sodium and the second coating layer consists of pure molybdenum. Both coating layers can be produced by means of DC sputtering (Kim, M. S. et al.: 21st European Photo Voltaic Solar Energy Conference, 4-8 Sep. 2006, Dresden, Germany, p 2011). This publication indicates that the grain size of the CIGS absorber layer decreases with increasing thickness of the sodium-doped coating layer. Furthermore, it is apparent that the function of the solar cell is impaired when the thickness of the sodium-doped coating layer exceeds the thickness of the sodium-free coating layer. It can be concluded therefrom that an excessively high sodium content in the CIGS absorber layer has an unfavourable effect on the efficiency of the solar cell.

DE 102 59 258 B4, too, is concerned with improving the efficiency of CIGS solar cells by addition of sodium. Here, it is emphasized that it is important to incorporate the sodium only in the late phase of the deposition of the absorber layer.

To be able to produce power economically by means of solar modules, these modules have to have a very long life. However, inward diffusion of oxygen or permeation of water can occur during the life cycle of the solar cell, which can lead to corrosion of the molybdenum back electrode layer since this is only moderately resistant to oxidation. Corrosion of the molybdenum layer can also occur even during the production process of the solar cell. In addition, the formation of molybdenum oxide can adversely affect the formation of the thin MoSₓ or MoSe_{y} layer on the interface of CIGS absorber layer/back electrode layer, as a result of which the ohmic contact is impaired.

DE 102 48 927 B4 proposes using a molybdenum back electrode layer containing from 1 to 33 atom % of nitrogen. Such layers are said to have a significantly higher corrosion resistance and a lower susceptibility to mechanical damage during the mechanical component structuring processes.

Component structuring processes are necessary in order to connect individual cells monolithically to form a module.

To be able to generate solar power inexpensively and at competitive prices in the future, the production costs for solar modules would firstly have to be reduced further and, secondly, the operating life of the modules would have to be increased. Optimised back electrode layers make a significant contribution to this.

It is therefore an object of the present invention to provide a thin-film solar cell having an Mo-containing back electrode layer, which has the following properties:
a high and constant efficiency due to sufficient and constant introduction of Na into the absorber layer;
a high long-term stability due to a high oxidation and corrosion resistance;
a defined ohmic contact due to formation of an MoSₓ/MoSeₓ layer having a constant thickness in the interface of back electrode layer/absorber layer;
good adhesion of layers to the adjoining materials and
low production costs as a result of a simple process.

A further object of the present invention is to provide a sputtering target for producing back electrode layers having the abovementioned properties. In addition, the sputtering target should have a uniform rate of removal of material over the sputtering area and not tend to undergo local partial melting.

This object is achieved according to the invention by the features of the independent claims.

According to the invention, at least one coating layer of the back electrode layer contains from 0.1 to 45 atom % of at least one element of the group consisting of titanium, zirconium, hafnium, vanadium, niobium, tantalum and tungsten. It has been found that the addition of these elements enables the long-term stability of the back electrode layer, the bonding to the absorber layer and the constancy of the incorporation of sodium into the absorber layer to be improved. At contents below 0.1 atom %, no satisfactory effect is achieved. If the alloying element content is above 45 atom %, the electrical conductivity decreases to unacceptably low values. The preferred content of titanium is from 1 to 30 atom %, that of zirconium is from 0.5 to 10 atom %, that of hafnium is from 0.5 to 10 atom %, that of vanadium is from 1 to 20 atom %, that of niobium is from 1 to 20 atom %, that of tantalum is from 1 to 15 atom % and that of tungsten is from 1 to 40 atom %. Particularly preferred contents are: titanium from 2 to 20 atom %, zirconium from 1 to 5 atom %, hafnium from 1 to 5 atom %, vanadium from 2 to 10 atom %, niobium from 2 to 10 atom %, tantalum from 2 to 10 atom % and tungsten from 5 to 35 atom %.

The addition of sodium can be carried out as per the prior art by thermal vaporisation of sodium-containing compounds, preferably during or after deposition of the absorber layer. However, sodium is preferably incorporated into the back electrode layer by means of sputtering during deposition of the back electrode layer. The sodium introduced into the back electrode during the deposition process diffuses from the back electrode layer into the absorber layer during subsequent processes which take place at elevated temperature (about 500° C.) as a result of its insolubility in the molybdenum matrix. This has the advantage that the additional process step of sodium deposition can be saved and the concentration can be set very precisely via the sodium content of the doped sputtering target. The maximum sodium content is 7.5 atom %, since satisfactory long-term stability and structural integrity of the layer are not ensured above this value. The best results are achieved at sodium contents of from 0.01 to 7.5 atom %. Below 0.01 atom % of sodium, the absorber layer requires additional sodium doping. The optimal sodium content depends on the structure (single coating layer/multiple coating layers), the thickness, the composition and the structure of the back electrode layer. Thus, in a single-coating layer structure, the best results are achieved at a sodium content of from 0.5 to 2.5 atom %.

High sodium contents of from 1.5 to 7.5 atom % are advantageous when the back electrode is made up of two or more coating layers. Thus, for example, a thin back electrode layer having a high sodium content can firstly be sputtered onto the substrate, followed by a pure molybdenum layer or a molybdenum layer having a low dopant content. The thinner the sodium-containing coating layer, the higher the advantageous sodium content of this coating layer. However, it is also possible firstly to deposit a pure molybdenum layer on the substrate, followed by the highly sodium-doped layer.

The diffusivity of sodium in the pure or sodium-doped molybdenum layer can be adjusted, for example, via the sputtering conditions, essentially by varying the argon gas pressure, and the content of elements which form a compound with sodium. For process engineering reasons, suitable compounds are compounds which have a melting point of greater than 500° C. If the melting point is below 500° C., local melting of the layer occurs in the thermal treatments necessary for production and this local melting can subsequently lead, in combination with the layer stresses, to hillock formation. Examples of sodium compounds having a melting point of greater than 500° C. are sodium oxides, sodium mixed oxides, sodium selenides and sodium sulphides. High oxygen, selenium and/or sulphur contents increase the rate of diffusion of sodium through the back electrode layer. It can be assumed that segregations at the grain boundaries represent preferential diffusion paths for sodium. To ensure a satisfactory long-term stability, microstructural integrity, satisfactory electrical conductivity and bonding to the adjacent materials, the total content of the elements which form a compound with sodium is limited to 7.5 atom %.

Furthermore, the oxygen is bound by titanium, zirconium, hafnium, vanadium, niobium, tantalum and/or tungsten. Since the content of free oxygen, i.e. oxygen capable of diffusion, is reduced thereby, unacceptably high diffusion of oxygen into the interface of back electrode layer/CIGS absorber layer or into the CIGS absorber layer is prevented. This ensures that an MoSeₓ or MoSₓ layer is formed in the interface of back electrode layer/CIGS absorber layer. Ohmic contact between the adjacent layers is thus made possible.

The preferred thickness of the back electrode layer is from 0.05 to 2 μm. In the case of layer thicknesses below 0.05 μm, the current carrying capacity of the layer is too low. At layer thicknesses above 2 μm, the layer stresses, layer adhesion and process costs are adversely affected.

A high long-term stability of the layer is achieved when it contains tungsten, titanium or niobium. Very good results have been able to be achieved at tungsten values of from 5 to 35 atom %. The combination of sodium with titanium or sodium with tungsten also leads to back electrode layers having excellent long-term stability.

The incorporation according to the invention of sodium into the back electrode layer makes it possible to use even sodium-free substrates such as metallic substrates composed of, for example, steel or titanium or substrates composed of a polymer material. It is thus possible to produce flexible chalcopyrite photovoltaic modules and thus to expand the range of applications considerably.

As mentioned above, it is advantageous to produce the back electrode layer by cathode atomisation (sputtering) using sputtering targets. Back electrode layers of thin-film solar cells having the above-described properties can be produced particularly advantageously using a sputtering target which consists of, apart from production-related impurities, from 0.1 to 45 atom % of at least one element from the group consisting of titanium, zirconium, hafnium, vanadium, niobium, tantalum and tungsten; from 0 to 7.5 atom % of sodium; from 0 to 7.5 atom % of one or more element(s) which forms/form a compound having a melting point of greater than 500° C. with sodium; a balance of at least 50 atom % of Mo.

The addition of sodium can be effected during or after deposition of the absorber layer and/or even during sputtering of the back electrode layer. The latter has the advantage of lower production costs combined with higher process reliability. An advantageous sputtering target for producing a sodium-doped back electrode layer consists of at least 50 atom % of Mo; from 0.01 to 45 atom % of at least one element from the group consisting of titanium, zirconium, hafnium, vanadium, niobium, tantalum and tungsten; also from 0.01 to 7.5 atom % of sodium and from 0.005 to 15 atom % of one or more element(s) which forms/form a compound having a melting point of greater than 500° C. with sodium. Furthermore, the material can have the usual impurities whose content depends on the production route or on the raw materials used. The impurity content is preferably <100 μg/g. When very pure raw materials are available, the impurity content can also be reduced further and is preferably <10 μg/g.

The preferred contents for titanium are from 1 to 30 atom %, those of zirconium are from 0.5 to 10 atom %, those of hafnium are from 0.5 to 10 atom %, those of vanadium are from 1 to 20 atom %, those of niobium are from 1 to 20 atom %, those of tantalum are from 1 to 15 atom % and those of tungsten are from 1 to 40 atom %. Particularly advantageous contents are titanium from 2 to 20 atom %, zirconium from 1 to 5 atom %, hafnium from 1 to 5 atom %, vanadium from 2 to 10 atom %, niobium from 2 to 10 atom %, tantalum from 2 to 10 atom % and tungsten from 5 to 35 atom %. These elements can be present as constituent of a sodium-containing compound, in elemental form and/or as a solution in the molybdenum matrix.

Furthermore, the sodium content is preferably from 0.1 to 5 atom %. The best results were able to be achieved using from 0.5 to 2.5 atom %. As mentioned above, it should be noted that the optimal sodium content depends greatly on the make-up, composition, thickness and structure of the back electrode layer.

The abovementioned alloying elements are incorporated into the back electrode layer in the coating process. If no reactive gases are used in the sputtering process, the contents of the respective alloying elements in the sputtering target and in the back electrode layer are approximately equal. The effects of the alloying elements on the efficiency and the operating life of solar cells have already been described for the back electrode layer. The use of reactive gases enables the composition of the back electrode layer to be made different from the composition of the sputtering target. Thus, for example, the oxygen content of the deposited layer can be reduced by use of hydrogen.

The layers deposited by means of the sputtering target according to the invention liberate sodium in a controlled manner, as a result of which a constant increase in efficiency of the solar cell is achieved. Particularly advantageous, sodium-containing compounds having a melting point of greater than 500° C. have been found to be sodium oxide, sodium mixed oxide, sodium selenide, sodium sulphide and the sodium halides. When sodium halides are used, it has to be ensured that the process is carried out in such a way that the respective halogen is not completely volatilised. Halogens which have a sufficiently high vapour pressure at the respective process temperatures are therefore advantageous. NaF is advantageous since fluoride liberated in the form of SF₆ or SeF₆ during the selenisation/sulphurisation step is given off. The use of sodium selenide and/or sodium sulphide is advantageous because diffusion of selenium and sulphur into the CIGS absorber layer does not adversely affect the efficiency of the solar cell.

Furthermore, it is advantageous in process engineering terms for Na₂O and/or Na₂O mixed oxides to be used. As preferred second component in mixed oxides, mention may be made of the oxides of the group consisting of titanium, zirconium, hafnium, vanadium, niobium, tantalum, tungsten, molybdenum, aluminium, germanium and silicon. These are, for example: xNa₂O.yWO₃, xNa₂O.yTiO₂, xNa₂O.HfO₂, xNa₂O.yZrO₂, xNa₂O.YV₂O₅, xNa₂O.yNb₂O₅, xNa₂O.yTa₂O₅, xNa₂O.yMoO₃, xNa₂O.yAl₂O₃, xNa₂O.yGeO₂ and xNa₂O.ySiO₂. The best results have been able to be achieved using xNa₂O.yWO₃ (sodium tungstate), xNa₂O.yNb₂O₅ (sodium niobate) and xNa₂O.yMoO₃ (sodium molybdate).

Mixed oxides made up of three or more oxides also display advantageous properties. If aluminium-, germanium- and/or silicon-containing mixed oxides are used, the advantageous contents of aluminium, germanium and silicon are in each case from 0.1 to 5 atom %.

Compounds having a melting point of greater than 500° C. are found to have sufficient stability under the production conditions. It is thus possible to produce the sputtering targets of the invention by, for example, infiltration of a porous molybdenum structure with the sodium-containing compounds. Process techniques such as hot pressing or hot isostatic pressing are also very suitable production processes.

In addition, at sodium contents below about 0.75 atom %, it is possible to make recourse to conventional production processes such as pressing, sintering with optional forming, for example by means of rolling. If compounds of sodium with at least one element of the group consisting of tungsten, niobium, titanium, zirconium, hafnium, vanadium, tantalum, molybdenum, germanium, silicon and aluminium are used, it is advantageous for the atomic ratio of sodium to the respective element to be <0.3.

During the deposition process, the constituents of the sputtering target are present in elemental form. If an oversupply of tungsten, niobium, titanium, zirconium, hafnium, vanadium, tantalum, molybdenum, germanium, silicon and/or aluminium is present, elemental sodium which is subsequently capable of diffusion and can diffuse into the absorber layer is also present in the layer as a result of thermodynamic and kinetic effects.

Furthermore, it has been found to be advantageous for the sputtering target material to have a skeletal structure of molybdenum or a molybdenum mixed crystal. The preferred grain size of the skeletal structure is from 0.1 to 50 μm. This ensures a uniform sputtering process without local partial melting. The volume content of the Mo-containing matrix phase is advantageously greater than 50%. The skeletal structure can be produced by using molybdenum powder or mixtures of molybdenum powder with titanium, zirconium, hafnium, tungsten, niobium, vanadium and/or tantalum having a Fisher particle size of preferably from 2 to 20 μm. Here, the powder is pressed with or without use of vaporisable space reservers and subsequently subjected to a sintering process at temperatures which are typically in the range from 1500° C. (2 μm powder) to 2300° C. (20 μm powder). Infiltration of a green body is also possible. When powders having a particle size below 2 μm are used, the development of closed porosity, which makes an infiltration step impossible, starts at excessively low temperatures. It is then not possible to achieve a molybdenum skeletal structure having sufficient skeletal strength combined with good infiltration properties and a stable microstructure by means of an infiltration process. The addition of oxidic sodium-containing compounds in powder form activates the densification during the heating operation and delays shrinkage in isothermal sintering.

It has been found to be advantageous to use molybdenum powder having a Fisher particle size of from 4 to 10 μm. This ensures open porosity at sintering temperatures of from 1600° C. (for 4 μm powder) to 2000° C. (for 6 μm powder) combined with sufficient sintering neck formation between the particles. If the powder particle size is above 20 μm, this leads to formation of very large pores. Since the capillary force is proportional to the pore size, the driving force is no longer sufficient for infiltration of these large pores. The sputtering behaviour and the quality of the deposited layer depend greatly on the distribution of the sodium-containing component in the molybdenum matrix. A uniform and controlled porosity thus leads to better sputtering behaviour and to preferred layer properties. The porosity after the sintering step is typically in the range from 15 to 25%. To achieve higher contents, it is necessary to use space reservers, e.g. in the form of vaporisable polymers. Since sodium oxide is very hygroscopic, the use of carbonates which decompose again during the infiltration process can be advantageous.

Hot isostatic pressing (HIP) has been found to be a further very advantageous process. Here, a powdered mixture or a green body produced from the powdered mixture is canned. The Fisher particle size of the Mo powder is preferably from 2 to 15 μm. Alloy powders having a comparatively low affinity for oxygen, for example W, preferably likewise have a Fisher particle size of from 2 to 15 μm. In the case of the very reactive elements titanium, zirconium, hafnium, tungsten, niobium, vanadium, tantalum and the sodium-containing compounds which sometimes likewise have a high affinity for oxygen, preference is given to using powders having a Fisher particle size of from 5 to 200 μm. Unalloyed steel is used as typical can material. If the corrosion resistance of steel towards the Na-containing compound is insufficient or the HIP temperature required is above 1200° C., it is possible to make recourse to, for example, a titanium can. To remove adsorbed oxygen or moisture, the can is preferably evacuated in the temperature range from 200 to 750° C. Hot isostatic pressing is preferably carried out at temperatures in the range from 1100 to 1400° C. and at pressures of from 50 to 300 MPa.

Hot pressing is also a suitable method of densification, and in this case a canning process can be dispensed with. However, it has been noted that sodium-containing compounds having a melting point of >1000° C. are advantageously used here in order to avoid expressing of this compound. It also has to be ensured that the vapour pressure of the sodium-containing compound is sufficiently low for an unacceptably high sodium loss during the pressing process to be avoided.

At sodium contents below 0.75 atom %, pressureless sintering, optionally followed by a forming step, can also be employed. Here, a water-soluble sodium compound, for example Na₂O.3SiO₂, is firstly dissolved in distilled water and this solution is admixed with MoO₃ powder, preferably having a specific surface area of >5 m²/g. However, a solid sodium-containing compound can also be mixed into the Mo oxide. The doped Mo oxide powder is then subjected to a two-stage reduction process, with MoO₃ being reduced to MoO₂ at about 550-650° C. in the first stage and MoO₂ being reduced to Mo metal powder at about 900-1100° C. in the second stage. As an alternative, the sodium-containing solution or the solid sodium-containing compound can also be added only to the MoO₂. The metal powder produced in this way has a Fisher particle size of from 2 to 6 μm and is sieved, homogenised, pressed and sintered at temperatures of from 1600 to 2200° C. It has to be noted that a loss of sodium occurs both in the reduction steps and in the sintering process, and this has to be taken into account correspondingly in the addition. This sodium loss can be reduced when sodium mixed oxides are used. Once again, preferred second components are the oxides of the group consisting of titanium, zirconium, hafnium, tungsten, niobium, vanadium, tantalum, molybdenum, aluminium, germanium and silicon.

The process techniques described make it possible to obtain sputtering targets having a density of from 97 to 100% of the theoretical density. Furthermore, it is possible to produce sputtering targets which have a macroscopically isotropic microstructure. For the purposes of the present invention, a macroscopically isotropic microstructure is a microstructure which, in a dimensional region of about 100 μm, has approximately the same proportions of the respective constituents of the microstructure in all three directions in space, with the sodium-containing regions not being larger than about 20 μm.

Furthermore, the sputtering targets of the invention are preferably configured as tubular targets. The coating plant is preferably integrated into the float process for producing the substrate glass, so that the waste heat of floating can be utilised to carry out the coating process at slightly elevated temperature, which has a favourable effect on the layer stresses. However, the sputtering targets of the invention can also be present in the form of flat targets.

The invention will hereinafter be illustrated by examples.

Molybdenum powder having a purity of 99.99 atom % (metallic purity, excluding W) and a Fisher particle size of 4.2 μm was mixed with the appropriate alloying constituents, which were introduced in powder (particle size measured by laser light scattering in the range from 10 to 70 μm) form in a diffusion mixer for 30 minutes. For samples 1 to 38, the respective alloying elements and their contents are shown in Table 1. The powder mixtures produced in this way were pressed by means of die pressing at a pressure of 270 MPa and a die diameter of 120 mm to form round discs. The discs were positioned in titanium capsules and evacuated at a temperature of 450° C. The extraction ports were then squashed tight and welded shut. Densification was carried out in a hot isostatic press at a temperature of 1400° C. and an argon pressure of 180 MPa. The density of the discs produced in this way was >99.5% of the theoretical density for all combinations of materials. The oxygen values of the sodium-free samples were determined by means of extraction with hot carrier gas. The results are likewise shown in Table 1.

The discs were then machined in order to produce sputtering targets appropriate for an experimental sputtering plant, with the diameter being 72 mm and the thickness 6 mm. Layers corresponding to the alloy composition of the target were deposited on a titanium substrate having dimensions of 40 mm×40 mm×0.7 mm by means of DC sputtering at 200 W, corresponding to 5 W/cm², and an argon pressure of 0.2 Pa. The deposition rate was in the range from 0.6 to 0.8 nm/sec depending on the alloy composition. The deposited layers had layer thicknesses in the range from 0.8 to 1.0 μm.

The specimens were then subjected to a low-temperature oxidation test at 85° C. and 85% relative atmospheric humidity. The test time was 200 hours.

While pure molybdenum layers display significant oxidation here and the molybdenum oxide layer thickness measured by SIMS depth profiling is about 20 nm, the specimens according to the invention optically show significantly lower oxidation. On the basis of the discoloration, the specimens were classified as −− (strong oxidation), −, 0 (medium oxidation), +, to ++ (virtually no oxidation). The results are once again shown in Table 1.

Selected layer systems (see Table 1) were subjected to thermal treatment at 500° C. for 15 minutes under reduced pressure. The sodium enrichment at the surface was then measured qualitatively by means of XPS and compared with the sodium enrichment of a pure molybdenum layer (comparative specimen) which was deposited on a soda-lime glass substrate and had likewise been ignited under reduced pressure at 500° C./15 min. The qualitative assessment reported in Table 1 was carried out according to the following criteria: −− (significantly lower sodium enrichment than in the comparative specimen), 0 (approximately the same sodium enrichment as in the comparative specimen), ++ (significantly higher sodium enrichment than in the comparative specimen).

TABLE 1

| | | | | | Oxidation test | XPS after |
|---|---|---|---|---|---|---|
| | Mole fraction | | | | 85° C./85% rel. | 500° C./15 min |
| | | Group | | | atm. humidity | vacuum ignition |
| | | consisting | | | t = 200 h | Na on layer surface |
| | | of Ti, Zr, | O | Addition of | oxidation | (little) −−, −, 0, +, |
| | | Hf, V, Nb, | kM (no | Na-containing | (strong) −−, −, | ++ (a lot) |
| Sample | Mo | Ta, W | measurement) | compound | 0, +, ++ (low) | nt (no test) |
| 0 | 0.9999 | — | 0.09 | — | −− | 0 |
| Prior art | | | | | | |
| 1 | Balance | Ti | 0.16 | — | 0 | nt |
| According to | | 0.01 | | | | |
| the invention | | | | | | |
| 2 | Balance | Ti | 0.20 | — | ++ | nt |
| According to | | 0.15 | | | | |
| the invention | | | | | | |
| 3 | Balance | Ti | 0.21 | — | ++ | nt |
| According to | | 0.30 | | | | |
| the invention | | | | | | |
| 4 | Balance | Zr | 0.17 | — | 0 | nt |
| According to | | 0.005 | | | | |
| the invention | | | | | | |
| 5 | Balance | Zr | 0.23 | — | 0 | nt |
| According to | | 0.05 | | | | |
| the invention | | | | | | |
| 6 | Balance | Hf | 0.16 | — | 0 | nt |
| According to | | 0.005 | | | | |
| the invention | | | | | | |
| 7 | Balance | Hf | 0.26 | — | + | nt |
| According to | | 0.05 | | | | |
| the invention | | | | | | |
| 8 | Balance | V | 0.11 | — | − | nt |
| According to | | 0.01 | | | | |
| the invention | | | | | | |
| 9 | Balance | V | 0.12 | — | 0 | nt |
| According to | | 0.10 | | | | |
| the invention | | | | | | |
| 10 | Balance | Nb | 0.07 | — | + | nt |
| According to | | 0.01 | | | | |
| the invention | | | | | | |
| 11 | Balance | Nb | 0.07 | — | ++ | nt |
| According to | | 0.10 | | | | |
| the invention | | | | | | |
| 12 | Balance | Ta | 0.06 | — | 0 | nt |
| According to | | 0.01 | | | | |
| the invention | | | | | | |
| 13 | Balance | Ta | 0.12 | — | + | nt |
| According to | | 0.10 | | | | |
| the invention | | | | | | |
| 14 | Balance | W | 0.06 | — | − | nt |
| According to | | 0.01 | | | | |
| the invention | | | | | | |
| 15 | Balance | W | 0.05 | — | 0 | nt |
| According to | | 0.10 | | | | |
| the invention | | | | | | |
| 16 | Balance | W | 0.08 | — | ++ | nt |
| According to | | 0.30 | | | | |
| the invention | | | | | | |
| 17 | Balance | W | 0.05 | — | ++ | nt |
| According to | | 0.40 | | | | |
| the invention | | | | | | |
| 18 | Balance | Ti | nm | Na₂MoO₄ | ++ | − |
| According to | | 0.15 | | 0.0005 | | |
| the invention | | | | | | |
| 19 | Balance | Ti | nm | Na₂MoO₄ | + | + |
| According to | | 0.15 | | 0.01 | | |
| the invention | | | | | | |
| 20 | Balance | Ti | nm | Na₂MoO₄ | + | + |
| According to | | 0.15 | | 0.05 | | |
| the invention | | | | | | |
| 21 | Balance | Ti | nm | Na₂MoO₄ | 0 | nt |
| According to | | 0.15 | | 0.10 | | |
| the invention | | | | | | |
| 22 | Balance | Ti | nm | Na₂MoO₄ | − | nt |
| According to | | 0.15 | | 0.15 | | |
| the invention | | | | | | |
| 23 | Balance | Ti | nm | Na₂MoO₄ | − | ++ |
| According to | | 0.15 | | 0.25 | | |
| the invention | | | | | | |
| 24 | Balance | Ti | nm | Na₂O | 0 | + |
| According to | | 0.15 | | 0.05 | | |
| the invention | | | | | | |
| 25 | Balance | Ti | nm | Na₂S | 0 | nt |
| According to | | 0.15 | | 0.05 | | |
| the invention | | | | | | |
| 26 | Balance | Ti | nm | Na₂Se | 0 | + |
| According to | | 0.15 | | 0.05 | | |
| the invention | | | | | | |
| 27 | Balance | Ti | nm | NaF | + | + |
| According to | | 0.15 | | 0.05 | | |
| the invention | | | | | | |
| 28 | Balance | Ti | nm | NaCl | 0 | nt |
| According to | | 0.15 | | 0.05 | | |
| the invention | | | | | | |
| 29 | Balance | Ti | nm | Na₂WO₄ | ++ | + |
| According to | | 0.15 | | 0.05 | | |
| the invention | | | | | | |
| 30 | Balance | Ti | nm | Na₂SiO₃ | + | + |
| According to | | 0.15 | | 0.05 | | |
| the invention | | | | | | |
| 31 | Balance | Ti | nm | Na₂GeO₃ | + | nt |
| According to | | 0.15 | | 0.05 | | |
| the invention | | | | | | |
| 32 | Balance | Ti | nm | Na₂Ti₃O₇ | ++ | + |
| According to | | 0.15 | | 0.05 | | |
| the invention | | | | | | |
| 32 | Balance | Ti | nm | Na₂NbO₄ | ++ | + |
| According to | | 0.15 | | 0.05 | | |
| the invention | | | | | | |
| 33 | Balance | Ti | nm | NaAlO₂ | 0 | nt |
| According to | | 0.15 | | 0.05 | | |
| the invention | | | | | | |
| 34 | Balance | W | nm | Na₂MoO₄ | + | nt |
| According to | | 0.30 | | 0.05 | | |
| the invention | | | | | | |
| 35 | Balance | W | nm | Na₂O | 0 | nt |
| According to | | 0.30 | | 0.05 | | |
| the invention | | | | | | |
| 36 | Balance | W | nm | Na₂WO₄ | ++ | + |
| According to | | 0.30 | | 0.05 | | |
| the invention | | | | | | |
| 37 | Balance | W | nm | Na₂Ti₃O₇ | ++ | nt |
| According to | | 0.30 | | 0.05 | | |
| the invention | | | | | | |
| 38 | Balance | W | Nm | Na₂NbO₄ | ++ | nt |
| According to | | 0.30 | | 0.05 | | |
| the invention | | | | | | |

1-23. (canceled)

24. A thin-film solar cell, comprising:
at least one substrate, a back electrode layer, an absorber layer, and a front contact layer;
said back electrode layer being formed of one or more coating layers and at least one coating layer of said back electrode layer consisting of:
from 0.1 to 45 atom % of at least one element selected from the group consisting of Ti, Zr, Hf, V, Nb, Ta, and W;
from 0 to 7.5 atom % of Na;
from 0 to 7.5 atom % of one or more elements forming a compound with Na having a melting point above 500° C.; and
balance of at least 50 atom % of Mo and impurities.

25. The thin-film solar cell according to claim 24, wherein at least one said coating layer of said back electrode layer contains from 0.01 to 7.5 atom % of Na.

26. The thin-film solar cell according to claim 24, wherein a content of Ti is from 1 to 30 atom %, a content of Zr is from 0.5 to 10 atom %, a content of Hf is from 0.5 to 10 atom %, a content of V is from 1 to 20 atom %, a content of Nb is from 1 to 20 atom %, a content of Ta is from 1 to 15 atom %, and a content of W is from 1 to 40 atom %.

27. The thin-film solar cell according to claim 26, wherein the content of Ti is from 2 to 20 atom %, the content of Zr is from 1 to 5 atom %, the content of Hf is from 1 to 5 atom %, the content of V is from 2 to 10 atom %, the content of Nb is from 2 to 10 atom %, the content of Ta is from 2 to 10 atom %, and the content of W is from 5 to 35 atom %.

28. The thin-film solar cell according to claim 24, wherein said back electrode layer contains from 0.01 to 7.5 atom % of at least one element selected from the group consisting of 0, Se, and S.

29. The thin-film solar cell according to claim 24, wherein said back electrode layer has a thickness of from 0.05 to 2 μm.

30. The thin-film solar cell according to claim 24, wherein at least one said coating layer of said back electrode layer contains Na and Ti.

31. The thin-film solar cell according to claim 24, wherein at least one said coating layer of said back electrode layer contains Na and W.

32. The thin-film solar cell according to claim 24, wherein said back electrode layer is formed of a single coating layer.

33. The thin-film solar cell according to claim 32, wherein said back electrode layer contains from 0.5 to 2.5 atom % of Na.

34. The thin-film solar cell according to claim 24, wherein said back electrode layer is formed of two coating layers.

35. The thin-film solar cell according to claim 34, wherein at least one of said two coating layers contains from 1.5 to 7.5 atom % of Na.

36. The thin-film solar cell according to claim 24, wherein said absorber layer is a chalcopyrite absorber layer.

37. A sputtering process, which comprises:
providing a sputtering target consisting of:
production dependent impurities;
from 0.1 to 45 atom % of at least one element selected from the group consisting of Ti, Zr, Hf, V, Nb, Ta, and W;
from 0 to 7.5 atom % of Na;
from 0 to 7.5 atom % of one or more elements that form a compound having a melting point of greater than 500° C. with Na; and
a balance of at least 50 atom % of Mo; and
sputtering from the sputtering target for producing a back electrode layer of the thin-film solar cell according to claim 24.

38. A sputtering target for producing a back electrode layer of a thin-film solar cell having a molybdenum content of at least 50 atom %, the sputtering target comprising:
from 0.1 to 45 atom % of at least one element selected from the group consisting of Ti, Zr, Hf, V, Nb, Ta, and W;
from 0.01 to 7.5 atom % of Na;
from 0.005 to 15 atom % of one or more elements that form a compound with Na having a melting point of greater than 500° C.; and
balance usual impurities.

39. The sputtering target according to claim 38, wherein:
a content of Ti is from 1 to 30 atom %;
a content of Zr is from 0.5 to 10 atom %;
a content of Hf is from 0.5 to 10 atom %;
a content of V is from 1 to 20 atom %;
a content of Nb is from 1 to 20 atom %;
a content of Ta is from 1 to 15 atom %; and
a content of W is from 1 to 40 atom %.

40. The sputtering target according to claim 39, wherein:
the content of Ti is from 2 to 20 atom %;
the content of Zr is from 1 to 5 atom %;
the content of Hf is from 1 to 5 atom %;
the content of V is from 2 to 10 atom %;
the content of Nb is from 2 to 10 atom %;
the content of Ta is from 2 to 10 atom %; and
the content of W is from 5 to 35 atom %.

41. The sputtering target according to claim 38, wherein a Na content is from 0.1 to 5 atom %.

42. The sputtering target according to claim 41, wherein the Na content is from 0.5 to 2.5 atom %.

43. The sputtering target according to claim 38, wherein the sodium compound is at least one compound from the group consisting of sodium oxide, sodium mixed oxide, sodium selenide, sodium sulfide, and sodium halides.

44. The sputtering target according to claim 38, wherein at least one element selected from the group consisting of Ti, Zr, Hf, V, Nb, Ta, and W is present in elemental form, as a solution in Mo, in the form of a mixed crystal, or as constituent of the sodium-containing compound.

45. The sputtering target according to claim 38, wherein the sodium-containing compound is a two-component or multi-component sodium mixed oxide, where one component is Na₂O and a further component is an oxide of at least one element selected from the group consisting of Ti, Zr, Hf, V, Nb, Ta, Cr, Mo, W, Si, and Ge.

46. The sputtering target according to claim 45, wherein the sodium-containing compound is at least one compound selected from the group consisting of sodium tungstate, sodium titanate, sodium niobate, and sodium molybdate.

47. The sputtering target according to claim 38, comprising a matrix phase composed of Mo or a Mo mixed crystal formed from one or more elements selected from the group consisting of Ti, Zr, Hf, V, Nb, Ta, and W, wherein a particle size of the matrix phase is from 0.1 to 50 μm and Na or the Na-containing compound is present in interstices of the matrix phase.
